(19) United States
(12) Patent Application Publication
(10) Pub. No.: US 2025/0329689 A1
(43) Pub. Date: Oct. 23, 2025

(54) SEMICONDUCTOR PACKAGE STRUCTURE

(71) Applicant: AP Memory Technology Corporation, Hsinchu County (TW)

(72) Inventors: Girish Nanjappa, HsinChu (TW); Wen-Liang Chen, HsinChu (TW); Chung-Chiang Huang, HsinChu (TW)

(73) Assignee: AP Memory Technology Corporation, Hsinchu County (TW)

(21) Appl. No.: 18/638,705

(22) Filed: Apr. 18, 2024

(51) Int. Cl. H01L 25/065; H01L 23/00; H01L 23/31; H01L 23/498; H10B 80/00

(52) U.S. Cl. CPC H01L 25/0657; H01L 23/3128; H01L 23/49816; H01L 24/16; H01L 24/32; H01L 24/48; H01L 24/73; H10B 80/00; H01L 2224/16145; H01L 2224/32225; H01L 2224/32245; H01L 2224/48225; H01L 2224/48245; H01L 2224/73207; H01L 2224/73253; H01L 2224/73265; H01L 2225/0651; H01L 2225/06513; H01L 2225/06568

(57) ABSTRACT

Provided is a semiconductor package structure including a carrier, a first chip, a second chip, a plurality of bonding wires, and a plurality of first bumps. The first chip is disposed on the carrier. The second chip is disposed on the first chip. The plurality of bonding wires is arranged to electrically connect the first chip and the carrier. The plurality of first bumps is arranged to electrically connect the second chip and the first chip. The plurality of first bumps is sandwiched between the second chip and the first chip.

### BACKGROUND

### Technical Field

The disclosure relates to a semiconductor package structure, and in particular to a semiconductor package structure with superior performance and lower manufacturing cost.

### Description of Related Art

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more of the smaller components to be integrated into a given area. These smaller electronic components also require smaller packages that utilize less area than previous packages. Currently, package-on-package (POP) structures are becoming increasingly popular for their compactness.

Generally speaking, in the POP structure including the memory chip and the system-on-chip (SoC), the memory chip is electrically connected to the system-on-chip through bonding wires. In this way, an input/output (I/O) connection path between the memory chip and the system-on-chip generated from a bonding wire is usually a few millimeters in length. Such an I/O connection path leads to an increase in memory I/O power consumption. In addition, since the memory chip is electrically connected to the system-on-chip through bonding wires, a large I/O driver is required, which further increases overall capacitance of the I/O connection path.

### SUMMARY

The disclosure provides a semiconductor package structure, wherein a first chip is disposed on and electrically connected to a carrier through bonding wires, and a second chip is disposed on and electrically connected to the first chip through bumps.

The semiconductor package structure of the disclosure includes a carrier, a first chip, a second chip, a plurality of bonding wires, and a plurality of first bumps. The first chip is disposed on the carrier. The second chip is disposed on the first chip. The plurality of bonding wires is arranged to electrically connect the first chip and the carrier. The plurality of first bumps is arranged to electrically connect the second chip and the first chip. The plurality of first bumps is sandwiched between the second chip and the first chip.

In an embodiment of the semiconductor package structure of the disclosure, at least one of the first bumps is arranged to be an Input/Output (I/O) connection path between the first chip and the second chip.

In an embodiment of the semiconductor package structure of the disclosure, the first chip is disposed on the carrier in a manner that a back surface of the first chip faces the carrier.

In embodiment of the semiconductor package structure of the disclosure, the second chip is disposed on the first chip in a manner that a front surface of the second chip faces a front surface of the first chip.

In embodiment of the semiconductor package structure of the disclosure, for each of the first bumps, one end of the first bump is attached to a first pad formed on the front surface of the first chip, and the other end of the first bump is attached to a second pad formed on the front surface of the second chip.

In embodiment of the semiconductor package structure of the disclosure, thicknesses of the first pad, the first bump, and the second pad substantially cause a distance between the first chip and the second chip, and the distance is ranged about 50˜150 μm.

In embodiment of the semiconductor package structure of the disclosure, for each of the bonding wires, one end of the bonding wire is connected to a first pad formed on the front surface of the first chip, and the other end of bonding wire is electrically connected to the carrier.

In an embodiment of the semiconductor package structure of the disclosure, the first chip includes a system-on-chip (SoC) with an advanced RISC machine (ARM) architecture.

In an embodiment of the semiconductor package structure of the disclosure, the second chip includes a memory chip.

In an embodiment of the semiconductor package structure of the disclosure, the memory chip includes a dynamic random access memory (DRAM)-based chip with a one-transistor-one-capacitor (1T1C) architecture.

In an embodiment of the semiconductor package structure of the disclosure, the first bump includes a micro-bump, a hybrid-bump or a nano-bump.

In an embodiment of the semiconductor package structure of the disclosure, a pitch between the first chip and the second chip is less than 1 mm.

In an embodiment of the semiconductor package structure of the disclosure, a pitch between the first chip and the second chip is less than 150 μm.

In an embodiment of the semiconductor package structure of the disclosure, a size of the second chip is 16 mm² or less.

In an embodiment of the semiconductor package structure of the disclosure, the carrier is a lead frame.

In an embodiment of the semiconductor package structure of the disclosure, the carrier is a printed circuit board (PCB) or a circuit substrate comprising a printed circuit board and an interposer disposed on and electrically connected to the printed circuit board.

In an embodiment of the semiconductor package structure of the disclosure, the semiconductor package structure further includes a plurality of second bumps disposed on a surface of the carrier opposite to the first chip.

In an embodiment of the semiconductor package structure of the disclosure, the plurality of first bumps includes at least 100 first bumps.

In an embodiment of the semiconductor package structure of the disclosure, the semiconductor package structure further includes an adhesive layer disposed between a back surface of the first chip and the carrier, and a material of the adhesive layer comprises Ajinomoto build-up film (ABF), polyimide resin or epoxy resin.

In an embodiment of the semiconductor package structure of the disclosure, the semiconductor package structure further includes an encapsulation layer at least encapsulating the carrier, the first chip, the plurality of bonding wires, the second chip and the plurality of first bumps, and a material of the encapsulation layer comprises a molding compound.

Based on the above, in the semiconductor package structure of the disclosure, the first chip is disposed on and electrically connected to the carrier through the bonding wires, and the second chip is disposed on and electrically connected to the first chip through bumps. Since, the first chip is electrically connected to the carrier through the bonding wires, the manufacturing costs may be reduced. In addition, since the second chip is electrically connected to the first chip through bumps, the length of the I/O connection path between the first chip and the second chip may be reduced. Therefore, the power consumption may be significantly reduced, so that the semiconductor package structure of the disclosure may have superior performance.

### BRIEF DESCRIPTION OF THE DRAWINGS

FIG. 1 is schematic cross-sectional views of the semiconductor package structure of the first embodiment of the disclosure.

FIG. 2 is schematic cross-sectional views of the semiconductor package structure of the second embodiment of the disclosure.

FIG. 3 shows a definition of a face side and a back side of a semiconductor structure or a semiconductor wafer.

### DESCRIPTION OF THE EMBODIMENTS

The embodiments are listed below and described in detail with the accompanying drawings, but the provided embodiments are not intended to limit the scope of the disclosure. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the disclosure.

In addition, the directional terms, such as “on”, “above”, “under” and “below” mentioned in the text are only used to refer to the direction of the drawings, and are not used to limit the disclosure.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

In each of the following embodiments, the semiconductor package structure at least includes chips stacked on the carrier, wherein a first chip is disposed on and electrically connected to the carrier through bonding wires and a second chip is disposed on and electrically connected to the first chip through bumps. Therefore, the power consumption may be significantly reduced. The semiconductor package structure of the embodiment of the disclosure will be described in detail below.

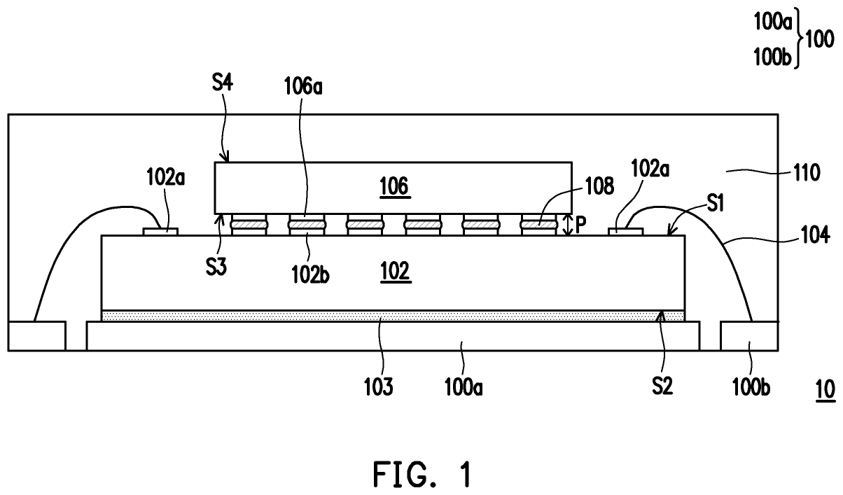

FIG. 1 is schematic cross-sectional views of the semiconductor package structure of the first embodiment of the disclosure.

Referring to FIG. 1, the semiconductor package structure 10 includes a carrier 100, a first chip 102, a plurality of bonding wires 104, a second chip 106, a plurality of first bumps 108 and an encapsulation layer 110. The carrier 100 is used to carry chips stacked thereon. In the present embodiment, the carrier 100 is a lead frame including a carrier portion 100a used to carry the stacked chips and a plurality of leads 100b surrounding the carrier portion 100a. In the present embodiment, the material of the carrier 100 may be metal or alloy, such as Cu or Cu alloy, but the disclosure is not limited thereto.

The first chip 102 is disposed on the carrier 100. In the present embodiment, the first chip 102 may be a system-on-chip (SoC). In the present embodiment, the system-on-chip has an advanced RISC machine (ARM) architecture, but the disclosure is not limited thereto. The first chip 102 has a front surface S1 and a back surface S2, and the first chip 102 is disposed on the carrier portion 100a of the carrier 100 in a manner that the back surface S2 of the first chip 102 faces the carrier 100. For the first chip 102, the memory I/O voltage may be ranged from 0.6 V to 1.2 V that is feasible to share the SoC core voltage. In addition, the I/O pin capacitance of the first chip 102 may be 0.5 pF or less.

In the present embodiment, the adhesive layer 103 may be disposed between the back surface S2 of the first chip 102 and the carrier portion 100a of the carrier 100. The material of the adhesive layer 103 may be Ajinomoto build-up film (ABF), polyimide resin or epoxy resin, but the disclosure is not limited thereto. The adhesive layer 103 is used as a die-attach film to fix the first chip 102.

In addition, the first chip 102 includes a plurality of pads located at the front surface S1. In detail, the first chip 102 includes pads 102a and pads 102b surrounded by the pads 102a. In the present embodiment, the pads 102a are located adjacent to the edge of the first chip 102. The first chip 102 may be electrically connected to the carrier 100 through the plurality of bonding wires 104 connecting the pads 102a and the leads 100b. In other words, for each of the bonding wires 104, one end of the bonding wire 104 is connected to the pad 102a formed on the front surface S1 of the first chip 102, and the other end of bonding wire 104 is connected to the carrier 100.

The second chip 106 is disposed on the first chip 102. The second chip 106 may be a memory chip, such as a dynamic random access memory (DRAM)-based chip. In the present embodiment, the second chip 106 has a one-transistor-one-capacitor (1T1C) architecture, but the disclosure is not limited thereto. The second chip 106 has a front surface S3 and a back surface S4, and the second chip 106 is disposed on the first chip 102 in a manner that the front surface S3 of the second chip 106 faces the front surface S1 of the first chip 102. That is, the second chip 106 is disposed on the first chip 102 in a flip-chip manner.

In addition, the second chip 106 includes a plurality of pads 106a located at the front surface S3. A plurality of bumps 108 are disposed between the pads 102b and the pads 106a. Therefore, the second chip 106 may be electrically connected to the first chip 102 through the plurality of bumps 108. In other words, for each of the bumps 108, one end of the bump 108 is attached to a pad 102b formed on the front surface S1 of the first chip 102, and the other end of the bump 108 is attached to a pad 106a formed on the front surface S3 of the second chip 106. Therefore, the pad 102b, the bump 108 and the pad 106 may be formed an I/O connection path between the first chip 102 and the second chip 106. Since the thickness of the pad 102b and the pad 106a are small, the bump 108 may be substantially considered as the I/O connection path, i.e., the bump 108 may be arranged to be the I/O connection path between the first chip 102 and the second chip 106, in which the I/O connection paths are arranged to transmit the input or output signals or power signal of the first chip 102.

In the present embodiment, the bump 108 may be a micro-bump, a hybrid-bump or a nano-bump. That is, in the present embodiment, the bump 108 may have a smaller size, which may be feasible to the fine pitches of the pads 106a of the second chip 106. In other words, in the present embodiment, the second chip 106 may therefore have a smaller size and may not have much layout penalty. In one embodiment, a size of the second chip 106 may be 16 mm² or less, the second chip 106 may support more than 64 I/O terminals, and the second chip 106 may include at least 100 first bumps 106a. In addition, the second chip 106 may have a memory array density less than or equal to 1 Gb.

Further, in the present embodiment, since the bump 108 may be a micro-bump, a hybrid-bump or a nano-bump, the pitch P between the first chip 102 and the second chip 106 may be reduced. Therefore, a shorter I/O connection path between the first chip 102 and the second chip 106 may be achieved. In the present embodiment, the pitch P between the first chip 102 and the second chip 106, i.e. the length of the I/O connection path between the first chip 102 and the second chip 106, may be less than 1 mm. In one embodiment, the pitch P may be less than 150 μm, less than 100 μm, or less than 50 μm. In other words, in one embodiment, the thicknesses of the pad 102b, the bump 108, and the pad 106a substantially may cause a distance between the first chip 102 and the second chip 106, and the distance may be ranged about 50˜150 μm.

The encapsulation layer 110 encapsulates the surface of the carrier 100, the first chip 102, the bonding wires 104, the second chip 106 and the bumps 108. The material of the encapsulation layer 110 may be a molding compound. In one embodiment, the material of the encapsulation layer 110 may be epoxy resin, but the disclosure is not limited thereto.

In the semiconductor package structure 10 of the present embodiment, the first chip 102 and the second chip 106 are stacked on the carrier 100. The first chip 102 is disposed on and electrically connected to the carrier 100 through the bonding wires 104, and thus the manufacturing costs may be reduced. In addition, the second chip 106 is disposed on and electrically connected to the first chip 102 through bumps 108, and thus the length of the I/O connection path between the first chip 102 and the second chip 106 may be reduced, thereby the power consumption of the first chip 102 as well as the second chip 106 may be significantly reduced. Therefore, the semiconductor package structure 10 of the present embodiment may have superior performance and lower manufacturing cost.

In the present embodiment, the first chip 102 and the second chip 106 are stacked on the lead frame, but the disclosure is not limited thereto. In other embodiments, the first chip 102 and the second chip 106 may be stacked on other types of carriers.

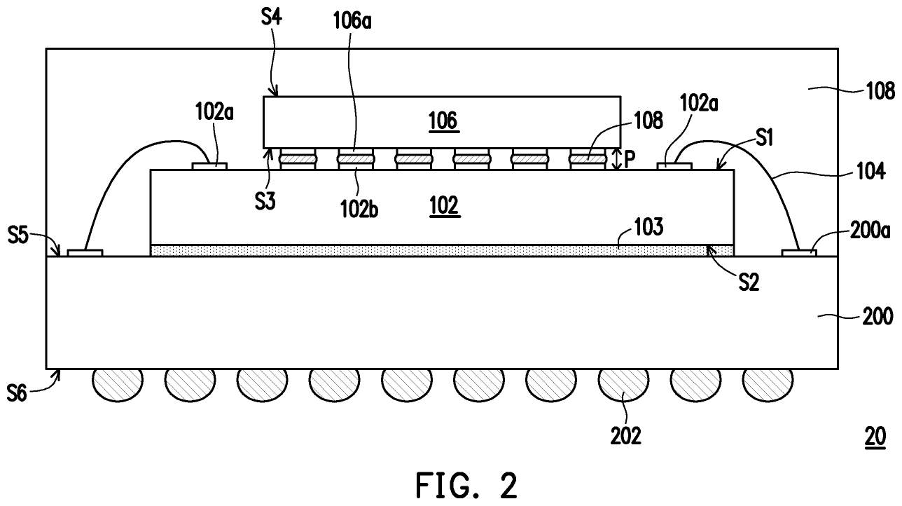

FIG. 2 is schematic cross-sectional views of the semiconductor package structure of the second embodiment of the disclosure. In the present embodiment, the same components as in the first embodiment will be represented by the same reference symbols and will not be described again.

Referring to FIG. 2, the difference between the semiconductor package structure 20 of the present embodiment and the semiconductor package structure 10 is that in the semiconductor package structure 20, the first chip 102 and the second chip 106 are stacked on the carrier 200. In the present embodiment, the carrier 200 may be a printed circuit board (PCB) or a circuit substrate including a printed circuit board and an interposer disposed on and electrically connected to the printed circuit board.

In addition, the carrier 200 has a first surface S5 and a second surface S6. The first surface S5 and the second surface S6 may be the front surface and the back surface of the carrier 200. The carrier 200 includes a plurality of pads 200a located at the first surface S5. Further, a plurality of bumps 202 are disposed on the second surface S6 of the carrier 200. The first chip 102 is disposed on the carrier 200 in a manner that the back surface S2 of the first chip 102 faces the first surface S5 of the carrier 200. In the present embodiment, the first chip 102 may be electrically connected to the carrier 200 through the bonding wires 104 connecting the pads 102a and the pads 200a. In other words, for each of the bonding wires 104, one end of the bonding wire 104 is connected to the pad 102a formed on the front surface S1 of the first chip 102, and the other end of bonding wire 104 is connected to the pad 200a formed on the first surface S5 of the carrier 200.

In the semiconductor package structure 20 of the present embodiment, the first chip 102 and the second chip 106 are stacked on the carrier 200. The first chip 102 is disposed on and electrically connected to the carrier 200 through the bonding wires 104, and thus the manufacturing costs may be reduced. In addition, the second chip 106 is disposed on and electrically connected to the first chip 102 through bumps 108, and thus the length of the I/O connection path between the first chip 102 and the second chip 106 may be reduced, thereby the power consumption may be significantly reduced. Therefore, the semiconductor package structure 20 of the present embodiment may have superior performance and lower manufacturing cost.

In summary, the semiconductor package structures of the embodiments have at least the following characteristics.
(1) The memory access power of the semiconductor package structure may be less 1 pj/b.
(2) The semiconductor package structure may have small density support of 64 Mb to 1 Gb.
(3) The semiconductor package structure may have excellent bandwidth support by wide I/O.
(4) The second chip 106 may be multi banks to enhance the random access efficiency.
(5) The I/O voltage of second chip 106 is feasible to SOC need.
(6) The semiconductor package structure may have affordable packaging, such as ball grid array (BGA) packaging or quad flat non-leaded (QFN) packaging.

In one embodiment, the semiconductor package structure may have the following characteristics compared with a common semiconductor package structure (DDR3L with wire-bond), as shown in Table 1.

TABLE 1

| | common semiconductor package | | semiconductor package | |
|---|---|---|---|---|
| | structure | | structure of the embodiment | |
| bottom chip size | ~6.5 mm × ~6.5 mm | | ~6.5 mm × ~6.5 mm or smaller | |
| memory size | 9 mm² (512 Mb DDR2 @F25) | | 7.25 mm² (512 Mb @F25) | |
| | 16.4 mm² (1 Gb DDR3L @ F25) | | 14.5 mm² (1 Gb @F25) | |
| package size | 9 mm × 9 mm QFN | | | |
| SOC connection | wire-bond to lead frame: ~150 wires | | | |
| memory connection | ~90 wire bond pads | | 188/376 bumps | |
| max bandwidth | 17 Gb/s (DDR2 x16) | | 64 Gb/s (x128) | |
| | 34 Gb/s (DDR3 x16) | | 128 Gb/s (x256) | |
| memory access power | 9.3 | pJ/b | <1 | pj/b |
| Memory Standby | 13.5 | mW | ~0.1 | mW |
| Power @ 25 C. | | | | |

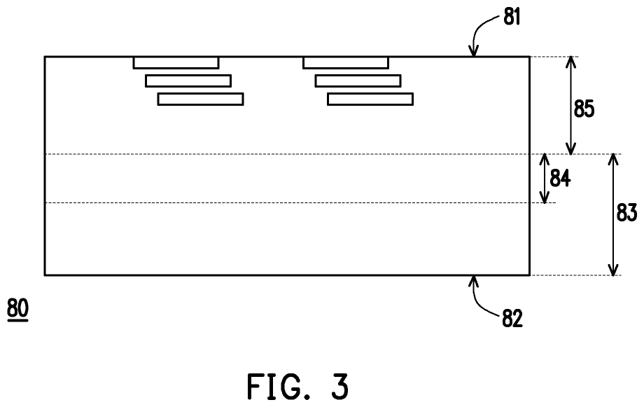

It is noted that, in the above description, the “front surface” (also known as face side) means a surface on which the back-end-of-line (BEOL) is formed, and “back surface” (also known as back side) means a surface of the semiconductor substrate, i.e., the opposite to the front surface. For the purpose of illustration, FIG. 3 shows a definition of a face side and a back side of a semiconductor structure or a semiconductor wafer. For a semiconductor structure 80 (e.g. the first chip 102 or the second chip 106 as previously shown in FIG. 1) or a wafer, the semiconductor structure may comprise a semiconductor substrate 83 and a back-end-of-line (BEOL) structure 85, in which a front-end-of-line (FEOL) structure 84 is formed in/on the semiconductor substrate 83. Active devices or semiconductor devices may be formed in the semiconductor substrate 83. According to the embodiments, the surface of the BEOL structure 85 may be the face side 81 of the semiconductor structure 80, and the surface of the semiconductor substrate 83 may be the back side 82 of the semiconductor structure 80. However, this is not a limitation of the present embodiments. The definition of the face side and the back side of a semiconductor structure may be switched.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor package structure, comprising:
a carrier;
a first chip, disposed on the carrier;
a second chip, disposed on the first chip;
a plurality of bonding wires, arranged to electrically connect the first chip and the carrier; and
a plurality of first bumps, arranged to electrically connect the second chip and the first chip,
wherein the plurality of first bumps is sandwiched between the second chip and the first chip.

2. The semiconductor package structure of claim 1, wherein at least one of the first bumps is arranged to be an Input/Output connection path between the first chip and the second chip.

3. The semiconductor package structure of claim 1, wherein the first chip is disposed on the carrier in a manner that a back surface of the first chip faces the carrier.

4. The semiconductor package structure of claim 1, wherein the second chip is disposed on the first chip in a manner that a front surface of the second chip faces a front surface of the first chip.

5. The semiconductor package structure of claim 4, wherein, for each of the first bumps, one end of the first bump is attached to a first pad formed on the front surface of the first chip, and the other end of the first bump is attached to a second pad formed on the front surface of the second chip.

6. The semiconductor package structure of claim 5, wherein thicknesses of the first pad, the first bump, and the second pad substantially cause a distance between the first chip and the second chip, and the distance is ranged about 50˜150 μm.

7. The semiconductor package structure of claim 4, wherein, for each of the bonding wires, one end of the bonding wire is connected to a first pad formed on the front surface of the first chip, and the other end of bonding wire is electrically connected to the carrier.

8. The semiconductor package structure of claim 1, wherein the first chip comprises a system-on-chip (SoC) with an advanced RISC machine (ARM) architecture.

9. The semiconductor package structure of claim 1, wherein the second chip comprises a memory chip.

10. The semiconductor package structure of claim 9, wherein the memory chip comprises a dynamic random access memory (DRAM)-based chip with a one-transistor-one-capacitor (1T1C) architecture.

11. The semiconductor package structure of claim 1, wherein the first bump comprises a micro-bump, a hybrid-bump or a nano-bump.

12. The semiconductor package structure of claim 1 wherein a pitch between the first chip and the second chip is less than 1 mm.

13. The semiconductor package structure of claim 1, wherein the pitch between the first chip and the second chip is less than 150 μm.

14. The semiconductor package structure of claim 1, wherein a size of the second chip is 16 mm² or less.

15. The semiconductor package structure of claim 1, wherein the carrier comprises a lead frame.

16. The semiconductor package structure of claim 1, wherein the carrier comprises a printed circuit board (PCB) or a circuit substrate comprising a printed circuit board and an interposer disposed on and electrically connected to the printed circuit board.

17. The semiconductor package structure of claim 16, further comprising a plurality of second bumps disposed on a surface of the carrier opposite to the first chip.

18. The semiconductor package structure of claim 1, wherein the plurality of first bumps comprises at least 100 first bumps.

19. The semiconductor package structure of claim 1, further comprising an adhesive layer disposed between a back surface of the first chip and the carrier, and a material of the adhesive layer comprises Ajinomoto build-up film (ABF), polyimide resin or epoxy resin.

20. The semiconductor package structure of claim 1, further comprising an encapsulation layer at least encapsulating the carrier, the first chip, the plurality of bonding wires, the second chip and the plurality of first bumps, and a material of the encapsulation layer comprises a molding compound.
